(19) United States
(12) Patent Application Publication
(10) Pub. No.: US 2010/0244101 A1
(43) Pub. Date: Sep. 30, 2010

(54) SEMICONDUCTOR DEVICE AND METHOD FOR MANUFACTURING THE SAME

(75) Inventors: Takuya Kokawa, Tokyo (JP); Sato Yoshihiro, Tokyo (JP); Kato Sadahiro, Tokyo (JP); Iwami Masayuki, Tokyo (JP)

Correspondence Address: TUROCY & WATSON, LLP, 127 Public Square, 57th Floor, Key Tower, CLEVELAND, OH, 44114, US

(73) Assignee: FURUKAWA ELECTRIC CO., LTD., Tokyo (JP)

(21) Appl. No.: 12/723,274

(22) Filed: Mar. 12, 2010

(30) Foreign Application Priority Data
Mar. 31, 2009 (JP) 2009-087354

(51) Int. Cl. H01L 29/267; H01L 21/20

(52) U.S. Cl. 257/201; 438/505; 257/E21.09; 257/E29.081

(57) ABSTRACT

There is provided a method for fabricating a semiconductor device capable of setting carbon concentration within crystal to a desirable value while improving electron mobility. The carbon concentration within a buffer layer is controlled by introducing material gas of hydrocarbon or organic compounds containing carbon such as propane as a dopant in forming the buffer layer by introducing trimethylgallium (TMGa) and ammonium (NH₃) as gaseous nitride compound semiconductor materials into a chamber in which a substrate is disposed.

### CROSS-REFERENCE TO RELATED APPLICATIONS

This application claims priority from Japanese patent application Serial No. 2009-087354, filed on Mar. 31, 2009, the entire content of which is incorporated herein by reference.

### BACKGROUND OF THE INVENTION

1. Field of the Invention

The present invention relates to a semiconductor device and a method for fabricating the same and more specifically to the semiconductor device and the method for fabricating the same using a gallium nitride (hereinafter referred to simply as GaN) semiconductor layer represented by (In_{X}Al_{1-X})_{Y}Ga_{1-Y}N (0≦X≦1, 0≦Y≦1).

2. Description of the Related Art

A field effect transistor (FET) using a nitride compound semiconductor, e.g., a GaN compound semiconductor, has such characteristics that a band gap energy is large as compared to GaAs materials for example and that it can stably operate even under such a high temperature environment close to 400 degree centigrade. Due to that, researches and developments of electronic devices such as FETs and high electron mobility transistors (HEMTs) using the nitride compound semiconductor or GaN in particular are being actively conducted lately.

Still more, due to the material characteristics described above, the electronic devices using the nitride compound semiconductor are not only receiving a fair amount of attention as power devices of micro and millimeter wavebands, they are greatly expected to be applied to highly-efficient inverters and converters.

However, it is necessary to miniaturize, to enhance reliability and to lower loss of the electronic devices using the nitride compound semiconductor in order to realize the application to the power devices of micro and millimeter wavebands and to the highly-efficient inverters and converters. Then, it becomes an important factor to increase a breakdown voltage and to lower ON resistance in realizing the power devices of micro and millimeter wavebands and the highly-efficient inverters and converters by the electronic devices using the nitride compound semiconductor.

The increase of the breakdown voltage of the semiconductor device is generally carried out by taking a method of suppressing a leak current from being generated within a buffer layer by increasing resistance of the buffer layer. When the resistance of the buffer layer is not increased, the leak current flows through the buffer layer even if a drain current is to be turned off by enlarging a depletion layer right under a gate electrode, so that the drain current cannot be completely turned off. Then, there is proposed a method of increasing the resistance of the buffer layer by doping carbon into the buffer layer as impurities (see Patent Document 1).

Meanwhile, it is important to reduce dislocation density within a crystal or edge dislocation density that forms a strain field for electrons in particular and to improve electron mobility in order to lower the ON resistance of the semiconductor device.

### [Patent Document 1] Japanese Patent Application Laid-Open No. 2007-251144

When a crystal is grown here by using a MOCVD method for example, auto-doping is generally carried out by using carbon contained in organic metal as a dopant. However, when the crystal is grown by using the MOCVD method or the like, the condition of reducing the dislocation density does not always match with the condition of increasing the carbon concentration. In fact, when the GaN semiconductor layer is grown by the MOCVD method, there arises a problem that although it is possible to improve the electron mobility by reducing the dislocation density by increasing the growth temperature, the breakdown voltage also deteriorates because the carbon concentration within the crystal decreases in the same time. In particular, the GaN epitaxially grown on a Si substrate has a problem that it is extremely difficult to reduce the dislocation density while keeping the carbon concentration high because dislocations occur in high concentration due to a large difference of lattice constants of the substrate and the GaN layer and an enough effect cannot be obtained even if the dislocation density is to be reduced by the growth condition.

Accordingly, in view of the problems described above, the invention aims at providing a semiconductor device and a method for fabricating the same capable of setting the carbon concentration within the crystal at a desirable value while improving the electron mobility.

### SUMMARY OF THE INVENTION

A method for fabricating a semiconductor device of one embodiment of the invention comprises a step of controlling carbon concentration of a nitride compound semiconductor layer by introducing material gas containing two or more carbons (C) in a molecular formula as a dopant in forming the nitride compound semiconductor layer on a Si substrate.

The semiconductor device according to one embodiment of the invention has the nitride compound semiconductor layer formed on the Si substrate, wherein the carbon concentration is equal to or more than 7×10¹⁸/cm³ and is equal to or less than 1×10²⁰/cm³ and a full width at half maximum of X-ray diffraction setting a (30-32) surface as a diffractive surface is equal to or less than 2100 arcsec. The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a section view showing a structure of a HEMT as a semiconductor element according to one embodiment of the invention;

FIG. 2 is a graph showing a relationship between carbon concentration and breakdown voltage within a buffer layer of the HEMT of one embodiment of the invention;

FIG. 3 is a graph showing a relationship between growth temperature and the carbon concentration within the buffer layer of the HEMT of one embodiment of the invention;

FIG. 4 is a graph showing a relationship between the carbon (C) concentration and a full width at half maximum (FWHM) of X-ray diffraction applied to a (30-32) surface as a diffractive surface;

FIG. 5 is a graph showing a case when propane is used as hydrocarbon and results when the carbon concentration within the buffer layer is changed by changing flow rate of propane gas in one embodiment of the invention; and

FIGS. 6A through 6D are processing diagrams showing a method for fabricating the HEMT according to one embodiment of the invention.

### DETAILED DESCRIPTION OF THE PREFERRED EMBODIMENTS

One embodiment of the invention will now be explained with reference to the drawings. It is noted that the same reference numerals denote the same or corresponding parts in the explanation of the embodiments and their overlapped explanation will be omitted here.

### Embodiment

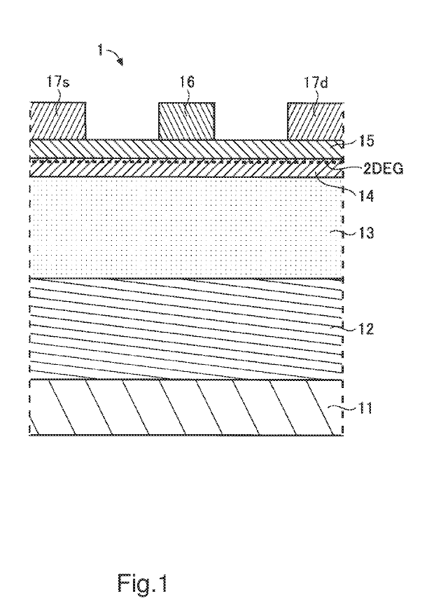

A method for fabricating a semiconductor device of one embodiment of the invention will now be explained in detail with reference to the drawings. It is noted that the invention is not limited by this embodiment. A HEMT 1 using a nitride compound semiconductor shown in FIG. 1 will be exemplified as the semiconductor device in the present embodiment.

### (Structure)

FIG. 1 is a section view showing a structure of the HEMT 1 as a semiconductor element according to one embodiment of the invention. As shown in FIG. 1, the HEMT 1 has the nitride compound semiconductor laminated through a buffer layer on a substrate 11 made of sapphire, Si, SiC or the like. Specifically, the HEMT 1 has a low-temperature buffer layer 12 made of GaN formed in low temperature, a buffer layer 13 made of GaN, a carrier drifting layer 14 made of undoped GaN and a carrier supplying layer 15 made of AlGaN laminated one after another on the substrate 11. In this laminate structure, junction planes of the carrier drifting layer 14 and the carrier supplying layer 15 form a hetero junction interface.

The HEMT 1 also has a source electrode 17s, a gate electrode 16 and a drain electrode 17d on the carrier supplying layer 15. The source electrode 17s and the drain electrode 17d as ohmic electrodes are formed by laminating an aluminum (Al) film, a titanium (Ti) film and a gold (Au) film for example one after another on the carrier supplying layer 15. The gate electrode 16 as a schottky electrode is formed by laminating a platinum (Pt) film and a gold (Au) film for example one after another on the carrier supplying layer 15.

In the HEMT 1 constructed as described above, the carrier supplying layer 15 has a large band gap energy as compared to the carrier drifting layer 14. Due to that, a two-dimensional electron gas layer 2DEG is formed right under the hetero junction interface between the carrier supplying layer 15 and the carrier drifting layer 14. This two-dimensional electron gas layer 2DEG may be utilized as carrier during operation. That is, when bias voltage is applied between the source electrode 17s and the drain electrode 17d, electrons supplied to the carrier drifting layer 14 drift rapidly within the two-dimensional electron gas layer 2DEG and move to the drain electrode 17d. At this time, the electrons moving from the source electrode 17s to the drain electrode 17d, i.e., a drain current, may be controlled by changing a thickness of the depletion layer right under the gate electrode 16 by controlling the voltage applied to the gate electrode 16. It is noted that the two-dimensional electron gas layer 2DEG in the carrier drifting layer 14 functions as so-called a channel layer.

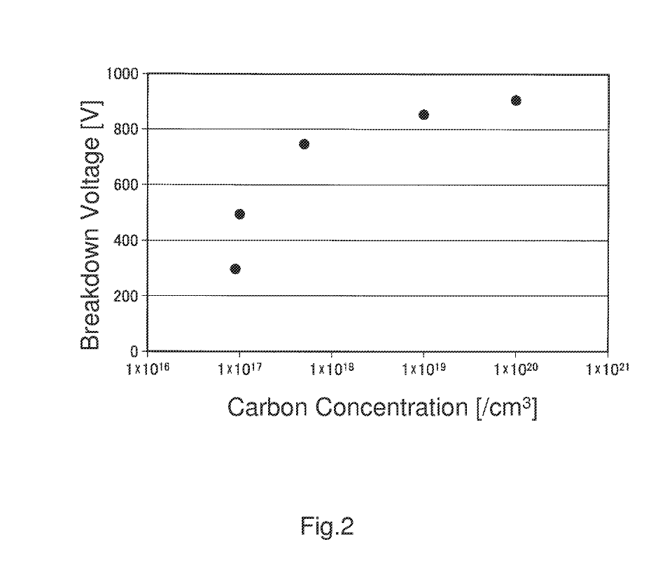

Here, the buffer layer 13 provided in the HEMT 1 will be explained. Resistance of the buffer layer 13 is increased by doping carbon impurities. As shown in FIG. 2, the higher the carbon concentration within the buffer layer 13, the higher the breakdown voltage of the HEMT 1 is. That is, the higher the carbon concentration within the buffer layer 13, the higher the breakdown voltage of the HEMT 1 is. It is noted that FIG. 2 is a graph showing the relationship between the carbon concentration and the breakdown voltage within the buffer layer 13 of the HEMT 1.

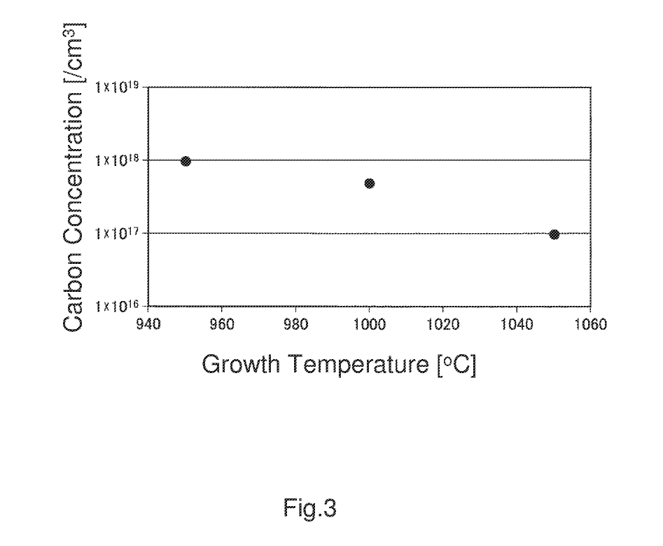

However, if substrate temperature during growth is increased for example for the purpose of lowering dislocation, the carbon concentration within the buffer layer 13 drops as shown in FIG. 3. Due to that, the breakdown voltage of the HEMT 1 deteriorate. It is noted that FIG. 3 is a graph showing the relationship between the growth temperature and the carbon concentration within the buffer layer 13.

Then, the inventor et al. found that it is preferable to dope hydrocarbon and organic compounds as dopants in order to increase the carbon concentration within the buffer layer 13. That is, it is possible to lower the dislocation density by optimizing the growth conditions of increasing the growth temperature for example and to keep the breakdown voltage by adding carbon that has decreased along the optimization by doping hydrocarbon and organic compounds as dopants. This method permits to obtain the nitride compound semiconductor layer (the buffer layer 13) in which the low dislocation density and the high breakdown voltage are both achieved.

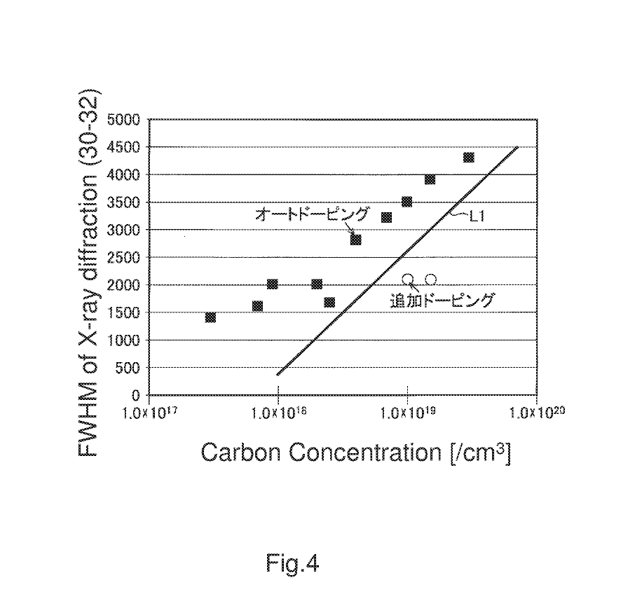

FIG. 4 is a graph showing a relationship between the carbon (C) concentration and a full width at half maximum (FWHM) of X-ray diffraction applied to a (30-32) surface as a diffractive surface. Here, it is known as shown in FIG. 4 that the full width at half maximum (FWHM) of X-ray diffraction correlates with the edge dislocation density within the semiconductor layer, that the smaller the full width at half maximum, the smaller the edge dislocation density and that the mobility is high as a result.

Still more, as it is apparent from the relationship between the carbon concentration and the full width at half maximum (FWHM) of X-ray diffraction applied to the (30-32) surface as the diffractive surface shown in FIG. 4, it was unable to form a film in a region where the carbon concentration is higher than a line L and the full width at half maximum is low in the conventional auto-doping. However, it becomes possible to form the film in the region in which the carbon concentration is higher than the line L and the full width at half maximum is low and to obtain a GaN epi-wafer on Si having high breakdown voltage and high electron mobility by additionally doping hydrocarbon and organic compounds as dopants. It is noted that in FIG. 4, smeared squares indicate the carbon concentration within the semiconductor layer attained by the auto-doping and hollow circles indicate carbon concentration within the semiconductor layer attained by the additional doping of the present embodiment.

Specifically, the carbon concentration is preferable to be equal to or more than 7×10¹⁸/cm³ and to be equal to or less than 1×10²⁰/cm³ in order to obtain the desirable breakdown voltage. Or, the carbon concentration is more preferable to be equal to or more than 1×10¹⁹/cm³ and to be equal to or less than 1×10²⁰/cm³. Still more, as for the dislocation density, the full width at half maximum (FWHM) of X-ray diffraction applied to the (30-32) surface as the diffractive surface is preferable to be equal to or less than 2100 arcsec. by considering the edge dislocation density that affects the breakdown voltage.

However, the hydrocarbon and organic compounds whose molecular weight is large are liquid around room temperature. Then, when the hydrocarbon and organic compounds are used as raw materials, the liquid material is introduced into a chamber of a reaction furnace for forming the buffer layer 13 by using a bubbler and by using nitrogen or hydrogen as carrier gas.

It is noted that in the formation of the buffer layer 13, the inventor et al. found that although almost no carbon concentration within the buffer layer 13 increases in methane when flow rates of trimethylgallium (TMGa) and ammonium (NH₃) that are raw materials of the nitride compound semiconductor layer (the buffer layer 13) and of hydrocarbon that is the material gas for doping carbon are set respectively at 700 μmol/min., 351 μmol/min. and 670 μmol/min. and when ethane, propane, butane, pentane, hexane, heptane, octane, ethylene, propylene, butene, pentene, hexane, heptene, octene, achethylene, propine, butyne, pentine, hexine, heptine, octine, dimethylhydrazine, dimethylamine or trimethyamine is used as the hydrocarbon, the carbon concentration increases when a material gas containing two or more carbons (C) in a molecular formula, e.g., hydrocarbon such as ethane and propane, is used. It can be seen from this fact that it is preferable to use the hydrocarbon containing two or more carbons (C) in the molecular formula as the dopant in using hydrocarbon as the dopant (material gas). That is, it is possible to increase the carbon concentration within the buffer layer 13 by using the hydrocarbon containing two or more carbons (C) in the molecular formula. In this case, the hydrocarbon may be saturated hydrocarbon whose molecular formula is represented by CₙH₂ₙ₊₂, CₙH₂ₙ or CₙH₂ₙ₋₂. Still more, the material gas used as the dopant may be a mixed gas containing at least one of ethane, propane, butane, pentane, hexane, heptane, octane, ethylene, propylene, butene, pentene, hexane, heptene, octene, achethylene, propine, butyne, pentine, hexine, heptine, octine, hydrazine organic compound, amine, propylamine, isopropylamine, dimethylamine or trimethyamine.

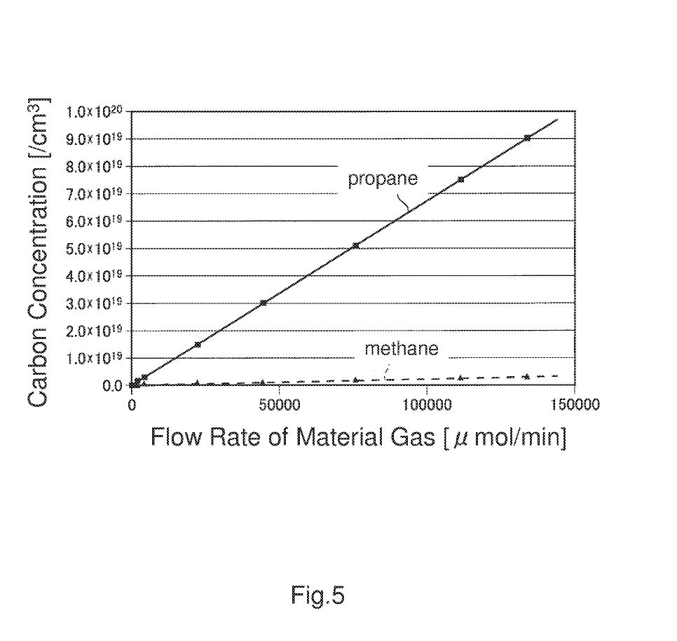

FIG. 5 shows results when the carbon concentration within the buffer layer 13 is changed by varying the flow rate of each material gas when the hydrocarbon such as methane or propane is used as the material gas of the carbon doping. It is noted that the flow rates of the trimethylgallium (TMGa) and ammonium (NH₃) are set respectively at 700 μmol/min. and 351 μmol/min. in this experiment. As it can be seen from FIG. 5, carbon (C) may be doped efficiently into the buffer layer 13 when propane gas is used as compared to the case of using methane gas as the material gas. It is also possible to read from FIG. 5 that the carbon concentration within the buffer layer 13 increases by increasing the flow rate of the propane gas. Such an effect appears in the same manner in cases of the other hydrocarbon.

As described above, it is possible to increase the carbon concentration within the buffer layer 13 and to form the buffer layer 13 having the high breakdown voltage as a result without relying on the growth conditions by doping carbon by using hydrocarbon as the raw material. It is needless to say that this applies not only to the buffer layer 13 but also to the other nitride compound semiconductor layers.

### (Fabrication Method)

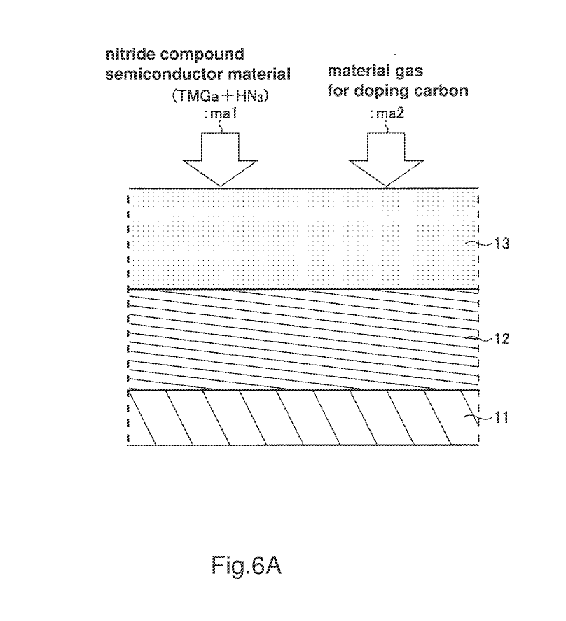

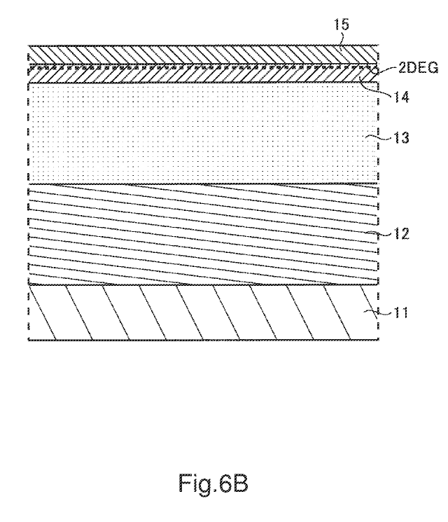

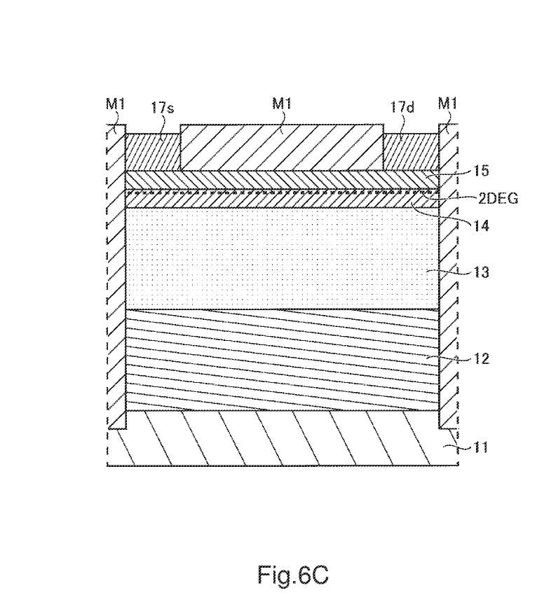

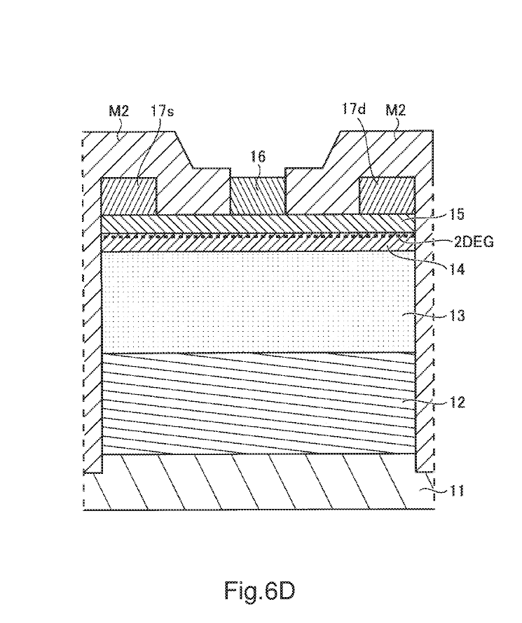

Next, a method for fabricating the HEMT 1 of the present embodiment will be explained in detail with reference to the drawings. FIGS. 6A through 6D are processing diagrams showing the method for fabricating the HEMT 1 of the present embodiment.

According to this fabrication method, the nitride compound semiconductor layer is laminated on the substrate 11 at first by the MOCVD (Metal Organic Chemical Vapor Deposition) method. Specifically, the substrate 11 made of Si is disposed within a chamber of a MOCVD system and then the trimethylgallium (TMGa) and ammonium (NH₃) that are the raw materials of the nitride compound semiconductor are introduced into the chamber with the flow rates of 700 μmol/min. and 351 μmol/min., respectively. Growth temperature at this time is set at 550 degree centigrade for example and a film thickness after growth is set at 30 nm for example. Thereby, the low-temperature buffer layer 12 made of GaN is epitaxially grown on the substrate 11.

Next, the buffer layer 13 which is 3 μm thick, is made of GaN and into which carbon is doped is epitaxially grown on the low-temperature buffer layer 12 as shown in FIG. 6A by introducing the nitride compound semiconductor material ma1 of TMGa and NH₃ and the material gas ma2 (carbon hydrate (propane)) for doping carbon into the chamber with the flow rates of 700 μmol/min. and 351 μmol/min., respectively.

Thus the material gas (hydrocarbon) containing carbon is introduced as the dopant independently from the nitride compound semiconductor material in forming the nitride compound semiconductor layer (the buffer layer 13) by introducing the gaseous nitride compound semiconductor materials (TMGa and NH₃) into the chamber in which the substrate 11 is disposed in the present embodiment, so that it becomes possible to control the carbon concentration within the nitride compound semiconductor layer independently from the growth conditions, e.g., the growth temperature, of the nitride compound semiconductor layer. In other words, it becomes possible to control the carbon concentration within the nitride compound semiconductor (GaN semiconductor layer, e.g., the buffer layer 13) independently from the auto-doping by organic metal materials by using the hydrocarbon or organic compounds that are the raw materials of the carbon-doping as the dopant.

It allows the carbon concentration within the crystal to be increased while reducing the dislocation density by increasing the growth temperature of the nitride compound semiconductor (GaN semiconductor layer, e.g., the buffer layer 13). As a result, it becomes possible to set the carbon concentration within the crystal to the desirable value while improving the electron mobility of the HEMT 1. It is noted that the growth temperature in growing the buffer layer 13 is set at 1050 degree centigrade for example. It is also assumed that propane for example is used as the hydrocarbon for doping carbon.

Next, the carrier drifting layer 14 which is 0.05 to 0.1 μm thick and is made of GaN is epitaxially grown on the buffer layer 13 by introducing TMGa and NH₃ into the chamber with the flow rates of 700 μmol/min. and 351 μmol/min., respectively. The growth temperature at this time is set at 1050 degree centigrade for example.

Next, the carrier supplying layer 15 which is 30 nm thick and made of AlGaN is epitaxially grown on the carrier drifting layer 14 as shown in FIG. 6B by introducing trimethylaluminum (TMAl), TMGa and NH₃ with flow rates of 3500 μmol/min., 700 μmol/min. and 351 μmol/min., respectively. The growth temperature at this time is 1050 degree centigrade for example. It is noted that hydrogen of 100% of concentration for example is used as a carrier gas in introducing TMAl, TMGa and NH₃ in the growing process of the respective nitride compound semiconductor layers.

After that, a silicon oxide (SiO₂) film is formed on the carrier drifting layer 14 by using the MOCVD method for example. This SiO₂ film is patterned by means of photolithographic technology to form a mask layer M1 in which openings A1 corresponding to shapes of the respective electrodes are formed in regions where the source electrode 17s and the drain electrode 17d are to be formed.

Next, Al, Ti and Au are deposited one after another within the openings A1 of the mask layer M1 to form the source electrode 17s and the drain electrode 17d made of a laminate film of Al/Ti/Au as shown in FIG. 6C.

Next, the mask layer M1 on the carrier supplying layer 15 is removed and a SiO₂ film is formed again on the carrier supplying layer 15. This is patterned to form a mask layer M2 in which an opening A2 corresponding to a shape of a gate electrode is formed in a region where the gate electrode 16 is to be formed.

Next, Pt and Au are deposited one after another within the opening A2 of the mask layer M2 to form the gate electrode 16 made of the laminate film of Pt/Au as shown in FIG. 6D. The HEMT 1 shown in FIG. 1 may be fabricated through the processing steps described above.

As described above, carbon is doped into the buffer layer 13 in relatively high concentration in the HEMT 1 of one embodiment. Thereby, the resistance of the buffer layer 13 may be increased, so that it is possible to reduce a leak current otherwise generated within the buffer layer 13 and to improve the breakdown voltage of the HEMT 1 as a result. That is, it is possible to realize the method for fabricating the semiconductor device capable of improving the carbon concentration within the crystal while improving the electron mobility.

It is noted that the carbon concentration within GaN (the buffer layer 13) is preferable to be around 1×10¹⁷/cm³ through 1×10²⁰/cm³. Because the breakdown voltage of the HEMT 1 may be equal to or more than 400V by setting the carbon concentration to be equal to or more than 1×10¹⁷/cm³, the HEMT 1 having practically effective characteristics may be fabricated. Meanwhile, it is possible to avoid an increase of the leak current because favorable crystalline and specularity of the surface of the layer may be obtained by setting the carbon concentration within GaN (the buffer layer 13) to be equal to or less than 1×10²⁰/cm³.

While the HEMT 1 according to one embodiment of the invention has been described above, the invention is not limited to that and may be modified variously within a scope not departing from the spirit of the invention. For instance, although one embodiment described above has been explained such that the low-temperature buffer layer 12 is interposed between the substrate 11 and the buffer layer 13, it is also possible to provide a buffer layer suited for the substrate and the nitride compound semiconductor layer appropriately. When a difference of lattice constants of the substrate and the nitride compound semiconductor layer is large in particular, it is possible to reduce stress applied to the nitride compound semiconductor layer by providing a buffer layer in which layers having largely different lattice constants are alternately laminated.

Specifically, a buffer layer in which Al layers and GaN layers, each around 1 to 3000 nm thick, are alternately laminated or a buffer layer in which InGaN layers and AlGaN layers are alternately laminated may be provided in a GaN semiconductor element for example. While the breakdown voltage of the semiconductor element is prone to drop, increasing a leak current, in this case because a two-dimensional electron gas layer is prone to be formed in each junction interface between the AlN layer and the GaN layer, it is possible to realize the high breakdown voltage while reducing the leak current by applying one embodiment described above.

Still more, although one embodiment described above has been explained such that the buffer layer 13 and the carrier drifting layer 14 are formed by using GaN and that the carrier supplying layer 15 is formed by using AlGaN, the invention is not limited to that and the respective layers may be formed by using a nitride compound semiconductor into which other elements are appropriately doped. For instance, at least one of the buffer layer 13 and the carrier drifting layer 14 may be formed by using a semiconductor material of (In_{X}Al_{1-X})_{Y}Ga_{1-Y}N (0≦X≦1, 0≦Y≦1). More specifically, the carrier drifting layer 14 may be formed by using InGaN for example.

Further, although one embodiment described above has been explained about the HEMT that is one type of FETs as the semiconductor element of the invention, the invention needs not be construed by limiting to the HEMT and is applicable to electronic devices that require high breakdown voltage such as FETs like MISFET (Metal Insulator Semiconductor FET), MOSFET (Metal Oxide Semiconductor FET) and MESFET (Metal semiconductor FET).

The invention is also applicable to various diodes such as a schottky diode other than the FETs. A diode in which cathode and anode electrodes are formed, instead of the source electrode 17s, the drain electrode 17d and the gate electrode 16 of the HEMT 1, may be formed as a diode to which the invention is applied.

It is noted that the embodiments described above are merely exemplary cases for carrying out the invention and the invention is not limited to them. It is obvious that various modifications of the invention may be made within the scope of the invention corresponding specifications and the like. Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for fabricating a semiconductor device, comprising a step of controlling carbon concentration of a nitride compound semiconductor layer by introducing material gas containing two or more carbons in a molecular formula as a dopant in forming the nitride compound semiconductor layer on a Si substrate.

2. The method for fabricating the semiconductor device according to claim 1, wherein the carbon concentration of the nitride compound semiconductor layer is equal to or more than 7×10¹⁸/cm³ and is equal to or less than 1×10²⁰/cm³.

3. The method for fabricating the semiconductor device according to claim 1, wherein the material gas is hydrocarbon or organic compounds containing carbon.

4. The method for fabricating the semiconductor device according to claim 1, wherein the material gas is hydrocarbon whose molecular formula is represented by CₙH₂ₙ₊₂ₙ, CₙH₂ₙ or CₙH₂ₙ₋₂ (where, n≧2).

5. The method for fabricating the semiconductor device according to claim 1, wherein the material gas is propane.

6. A semiconductor device comprising a nitride compound semiconductor layer formed on a Si substrate, wherein
the nitride compound semiconductor layer has carbon concentration equal to or more than 7×10¹⁸/cm³ and equal to or less than 1×10²⁰/cm³ and has a full width at half maximum of X-ray diffraction setting a (30-32) surface as a diffractive surface is equal to or less than 2100 arcsec.
